(19) United States
(12) Patent Application Publication
(10) Pub. No.: US 2024/0145659 A1
(43) Pub. Date: May 2, 2024

(54) COMPONENT HAVING STRUCTURED LEAD FRAME AND HOUSING BODY AND METHOD FOR PRODUCING THE COMPONENT

(71) Applicant: ams-OSRAM International GmbH, Regensburg (DE)

(72) Inventors: Matthias Goldbach, Pentling (DE); Georg Bogner, Lappersdorf (DE); Theo Kaiser, Kõfering (DE)

(21) Appl. No.: 18/547,417

(22) PCT Filed: Apr. 5, 2022
(86) PCT No.: PCT/EP2022/058957

§ 371 Date: Aug. 22, 2023

(30) Foreign Application Priority Data
Apr. 7, 2021 (DE) 10 2021 108 604.3

(51) Int. Cl. H01L 33/62; H01L 33/48

(52) U.S. Cl. CPC H01L 33/62; H01L 33/486; H01L 2933/0066

(57) ABSTRACT

In an embodiment, a component includes a lead frame, a semiconductor chip and a housing body, wherein the lead frame has a first subregion and a second subregion laterally spaced from the first subregion, wherein the housing body laterally encloses the first subregion and the second subregion and thereby mechanically connects the first subregion to the second subregion, wherein the semiconductor chip is arranged on a mounting surface of the first subregion and is electrically conductively connected to the subregions of the lead frame, wherein the first subregion has a first local elevation, which vertically projects beyond at least one edge region of the first subregion, and, in top view of the mounting surface, at least partially surrounds the semiconductor chip, and wherein, in the top view of the mounting surface, the housing body completely covers the first local elevation and does not cover the semiconductor chip.

### CROSS-REFERENCE TO RELATED APPLICATIONS

This patent application is a national phase filing under section 371 of PCT/EP2022/058957, filed Apr. 5, 2022, which claims the priority of German patent application 102021108604.3, filed Apr. 7, 2021, each of which is incorporated herein by reference in its entirety.

### TECHNICAL FIELD

A component having a structured lead frame and a housing body is provided. Furthermore, a method for producing a component, in particular the component with the structured lead frame and the housing body, is provided.

### BACKGROUND

To achieve increased corrosion stability, a component should be protected from external environmental influences, for example from the penetration of harmful gases or moisture. In particular, the harmful gases can enter the component from above through an encapsulation layer, a potting compound or laterally between a lead frame and housing material of a housing body. Metallic surfaces of the component, for example side walls of a cavity or mounting surface of the lead frame, can be damaged, for example oxidized, by the penetration of the harmful gases. In particular, surfaces with an Ag coating or copper surfaces are especially susceptible to environmental influences.

### SUMMARY

Embodiments provide a component, in particular an optoelectronic component, with high compactness and increased corrosion stability. Further embodiments provide a reliable and cost-efficient method for producing a component, in particular a component described herein.

According to at least one embodiment of a component, it comprises a lead frame and a semiconductor chip arranged on the lead frame. The semiconductor chip is in particular configured for generating or detecting electromagnetic radiation. The semiconductor chip may comprise a semiconductor body having, for example, a first semiconductor layer of a first charge carrier type, a second semiconductor layer of a second charge carrier type, and an active region located therebetween. For example, the semiconductor body is based on a III-V semiconductor compound material or on a II-VI semiconductor compound material. For example, the active region is a pn junction region. In operation of the component, the active region is particularly configured to generate electromagnetic radiation, for instance in the ultraviolet, infrared, or visible spectral regions.

The lead frame is configured in particular for external electrical contacting of the component, for instance of the semiconductor body. The lead frame can have a first subregion and a second subregion laterally spaced from the first subregion, wherein the first subregion and the second subregion are assigned to different electrical polarities of the component. For example, the first subregion is configured to electrically contact the first semiconductor layer. The second subregion of the lead frame may be configured for electrically contacting the second semiconductor layer.

For example, the semiconductor chip is arranged on and electrically conductively connected to the first subregion. The semiconductor chip may project beyond the first subregion along a vertical direction, or vice versa, for example when the semiconductor chip is arranged in a depression of the first subregion. In top view, the semiconductor chip and the second subregion of the lead frame may be arranged without overlap. In this case, the semiconductor chip is arranged exclusively on the first subregion of the lead frame. The semiconductor chip may be electrically conductively connected to the first subregion or to the second subregion of the lead frame via an electrical connection, for instance via a bonding wire. It is possible for the semiconductor chip to be electrically conductively connected directly to the first subregion of the lead frame via its rear side and an electrically conductive connecting layer.

A lateral direction is understood to mean a direction that is directed in particular parallel to a main extension surface of the lead frame, for example parallel to a mounting surface of the first subregion or of the second subregion of the lead frame. A vertical direction is understood to be a direction that is directed, in particular, perpendicular to the main extension surface of the lead frame or to the mounting surface of the first subregion or of the second subregion of the lead frame. The vertical direction and the lateral direction are orthogonal to each other.

According to at least one embodiment of the component, it has a housing body. In lateral directions, the lead frame can be enclosed, in particular completely enclosed, by the housing body. In particular, the lead frame does not project laterally and/or vertically beyond the housing body at any point. All lateral side surfaces of the lead frame can be flush with side surfaces of the housing body or covered by the material of the housing body. At the height of at least one vertical plane, both the first subregion and the second subregion of the lead frame may be enclosed, for example completely enclosed, by the housing body in lateral directions. In particular, the first subregion is mechanically connected to the second subregion of the lead frame by the housing body. If the first subregion is laterally spaced from the second subregion by an intermediate region, the intermediate region may be filled, for example completely filled, by the material of the housing body.

In a top view of a rear side of the component, the first subregion and/or the second subregion of the lead frame can be not covered in regions by the housing body. At the rear side of the component, the first subregion and/or the second subregion of the lead frame can thus be accessible at least in regions. In a top view of a front side of the component, the first subregion and/or the second subregion of the lead frame may not be covered in regions by the material of the housing body. Surface of the first subregion or of the second subregion that is not covered by the material of the housing body when viewed from the front side of the component may form a mounting surface of the first or second subregion. In particular, the semiconductor chip is arranged on such a mounting surface.

According to at least one embodiment of the component, the first subregion or the second subregion of the lead frame has a local elevation. Along a vertical direction, the local elevation may extend beyond at least one edge or one edge region of the first or second subregion of the lead frame adjacent to the local elevation. In particular, the edge is an upper edge of the first or second subregion to which the edge region of the first or second subregion is adjacent. In a top view of the front side of the component, the housing body may completely cover the local elevation. Thus, the local elevation may serve as an anchoring structure for attaching the housing body to the lead frame. For example, the semiconductor chip is disposed on the first subregion, wherein the first subregion comprises the local elevation.

An edge, in particular an outer edge or an upper edge, of a subregion of the lead frame is understood to mean, for example, a common connecting line between a side surface of the subregion and a side surface of the local elevation of the subregion. If the local elevation projects beyond the edge of the subregion along the vertical direction and thus an edge region adjacent to the edge, a front-side surface of the local elevation is located at a higher vertical level than the associated edge or the associated edge region of the subregion. An edge region of the subregion is understood to be a region that is directly adjacent to an edge, in particular an outer edge or an upper edge of the subregion. The edge region may be formed at least in part by side surfaces of the local elevation.

For example, in top view of the front side, the local elevation runs along at least one edge, along at least two edges, along three edges, or along all edges of the associated subregion of the lead frame. In particular, in top view, the local elevation extends along at least one side surface, along at least two side surfaces, along three side surfaces, or along all side surfaces of the semiconductor chip. In this sense, the semiconductor chip is at least partially or completely laterally enclosed by the local elevation when viewed from the front side of the component in a top view. Along the vertical direction, it is not mandatory that the local elevation projects beyond the semiconductor chip. Along the vertical direction, the semiconductor chip may project beyond the local elevation, or vice versa.

According to at least one embodiment of the component, the first subregion has a first local elevation and the second subregion has a second local elevation. When viewed from the front side of the component, the first local elevation and the second local elevation may have different geometries or similar geometries. If the first local elevation and the second local elevation have similar geometry, they can both be strip-shaped, L-shaped, U-shaped or frame-shaped.

In this disclosure, the features described in connection with the first local elevation may also be used for the second local elevation, or at least analogously used mutatis mutandis, and vice versa. Furthermore, the first local elevation and the second local elevation may have the same or different vertical height and/or lateral width, or may be oriented in the same manner or differently on the lead frame. In a top view of the front side of the component, the first local elevation and the second local elevation can, for example, be formed or arranged mirror-symmetrically except for their lateral and/or vertical extent—at least from a geometric point of view.

In at least one embodiment of a component, it comprises a lead frame, a semiconductor chip, and a housing body. The lead frame has a first subregion and a second subregion laterally spaced from the first subregion, wherein the housing body laterally encloses the first subregion and the second subregion, and thereby mechanically connects the first subregion to the second subregion. The semiconductor chip is disposed on a mounting surface of the first subregion and is electrically conductively connected to the subregions of the lead frame. The first subregion has a first local elevation that vertically projects beyond at least one edge region of the first subregion and, in a top view of the mounting surface, at least partially surrounds the semiconductor chip. In a top view of the mounting surface, the housing body completely covers the first local elevation, and the semiconductor chip is not covered by the housing body.

Because the housing body completely covers the first local elevation, the first local elevation acts as an anchoring structure to increase a mechanical connection between the first subregion of the lead frame and the housing body. Since the first local elevation is located between the semiconductor chip and one side surface or more side surfaces of the housing body when viewed from above, the first local elevation acts as a barrier to impede or prevent lateral penetration of moisture or harmful gases from an external environment toward the semiconductor chip. If, for example, a gap occurs between the lead frame and the housing body on a side surface of the component or the housing body, for example due to delamination at an interface between two different materials, the propagation of this gap is stopped at the local elevation at the latest. The local elevation thus protects the semiconductor chip as well as the mounting surface from external environmental influences, in particular from the penetration of harmful gases.

According to at least one embodiment of the component, the first local elevation—in top view of the mounting surface—extends along at least two or three or along all side surfaces of the semiconductor chip. The first local elevation may extend along at least two or three or along all edges of the first subregion.

According to at least one embodiment of the component, the first local elevation—in top view of the mounting surface—completely encloses the semiconductor chip. In this case, the first local elevation is frame-shaped.

According to at least one embodiment of the component, the first local elevation has a front-side surface that is at the same vertical level as the mounting surface of the first subregion. For example, the front-side surface of the first local elevation is at a higher vertical level than some or all of the edges of the first subregion. In particular, such edges are outer top edges of the first subregion.

According to at least one embodiment of the component, the first subregion has a first local depression adjacent to the first local elevation, wherein the first local depression is filled, in particular completely filled, with a material of the housing body. Along lateral direction, the first local elevation is located between the local depression and the edge region of the first subregion adjacent to the first local elevation.

According to at least one embodiment of the component, the first local depression and the first local elevation extend parallel to each other along lateral directions. The local depression and/or the first local elevation can run parallel to the outer edge or to the lowered edge region, or parallel to the outer edges or to the lowered edge regions of the first subregion.

According to at least one embodiment of the component, the first local depression—in top view of the mounting surface—extends along at least two or three or along all side surfaces of the semiconductor chip. The local depression thus encloses the semiconductor chip at least partially or completely.

According to at least one embodiment of the component, the first local depression bounds the mounting surface in at least one lateral direction or in exactly two, exactly three or in all lateral directions. In particular, the first local depression is completely filled by a material of the housing body. The mounting surface may be free or at least regionally free from being covered by the material of the housing body. However, within manufacturing tolerances, the mounting surface may be unintentionally covered by the material of the housing body in places.

According to at least one embodiment of the component, the first local elevation projects along a vertical direction beyond the mounting surface of the first subregion. In other words, the mounting surface is on a lower vertical plane than a front-side surface of the first local elevation.

According to at least one embodiment of the component, the first local elevation bounds the mounting surface in at least one lateral direction or in two, three or all lateral directions. In this regard, it is possible that the first subregion comprises a front-side partial surface that is arranged between the first local elevation and the mounting surface in top view. In top view, the front-side partial surface may be covered in regions or completely by a material of the housing body.

For example, the first local elevation is strip-shaped, L-shaped, U-shaped, or frame-shaped. The first local elevation may partially or completely enclose the mounting surface. If the local elevation is L-shaped, it may bound the mounting surface or semiconductor chip in exactly two lateral directions. If the local elevation is U-shaped, it can limit the mounting surface or the semiconductor chip in exactly three lateral directions. If the local elevation is frame-shaped, it can limit or enclose the mounting surface or the semiconductor chip in all lateral directions in top view.

According to at least one embodiment of the component, at least one or a plurality of the edge regions, in particular the lowered edge regions of the first subregion, are curved at least in regions. The edge region/s can have concave or convex surface/s. The curved surface of the edge region/s of the first subregion forms a transition region, in particular a continuous transition region between the front-side surface of the first local elevation and the side surfaces of the first subregion.

An edge region or a curved edge region of the subregion of the lead frame is understood to mean in particular a transition region between a front-side surface of the local elevation and a side surface of the subregion or of the lead frame. If the local elevation is directly adjacent to the edge of the lead frame, the associated, for instance lowered edge region of the lead frame is defined by a side surface of the local elevation.

According to at least one embodiment of the component, the second subregion of the lead frame has a second local elevation that vertically projects beyond at least one edge region of the second subregion. The first local elevation and the second local elevation may have similar geometry in top view, i.e. similar shapes. It is not necessary that they have the same geometric size or spatial extent.

According to at least one embodiment of the component, it comprises a protection diode. The protection diode may be arranged on the second subregion of the lead frame. For example, the protection diode is connected to the semiconductor chip in an anti-parallel manner. For example, the protection diode is arranged on a mounting surface of the second subregion. In a top view of the mounting surface, the protection diode may be partially or completely enclosed by the second local elevation in lateral directions. Quite analogously to the first local elevation, which prevents moisture or harmful gases from penetrating to the semiconductor chip, the second local elevation can protect the protection diode or the semiconductor chip from environmental influences for instance moisture or harmful gases.

According to at least one embodiment of the component, the first subregion and/or the second subregion have/has a solder control structure being an integral part of the lead frame. For example, the solder control structure is visible from the outside on a side surface of the component.

According to at least one embodiment of the component, the first subregion is formed in one piece with the first local elevation and/or with the solder control structure. In other words, the first local elevation and/or the solder control structure are integral parts of the first lead frame. The first subregion may have lateral connecting bars. The local elevation, the solder control structure, the connecting bars and the remaining integral parts of the first subregion may be made as a whole in one piece, thus being formed in one piece and being formed from the same material.

A method of manufacturing a component, for instance a component described herein, is disclosed. According to at least one embodiment of the method, double-etching is performed on a front side of the first subregion of the lead frame to form the first local elevation on the front side. The housing body is formed, wherein material of the housing body completely covers the first local elevation and is anchored to the first local elevation. The local elevation formed by the double-etching projects along the vertical direction beyond at least one edge region of the first subregion. Also, the local elevation may project along the vertical direction beyond a depression or a mounting surface of the first subregion. In particular, in top view, the first local elevation is located between the edge region of the first subregion adjacent to the first local elevation and the depression or mounting surface of the first subregion.

According to at least one embodiment of the method, the housing body is applied to and around the lead frame by a casting process or a plastic molding process. The term “casting process” or “plastic molding process” is generally understood to mean a process by which a molding compound, in this case the housing body, is formed according to a predetermined shape, preferably under the action of pressure, and, if necessary, cured. In particular, the term “casting process” or “plastic molding process” includes at least dispensing, jet dispensing, molding, injection molding, transfer molding and compression molding. The housing body is formed in particular from a plastic material, in particular from a potting/molding material or from a castable material.

According to at least one embodiment of the method, a plurality of lead frames each having a first subregion and a second subregion are provided, wherein the first subregions of adjacent lead frames are mechanically connected to each other via connecting bars. Double-etching to form the first local elevation is performed on the front side of the respective first subregions, wherein the front side is not etched at the positions of the connecting bars. The components are singulated after forming the housing body, wherein the housing body and the connecting bars are severed.

The second local elevation of the second subregion of the lead frame can be formed quite analogously to the first local elevation, for example by double-etching. For example, the second subregions of adjacent lead frames are mechanically connected to each other via further connecting bars. When performing double-etching to form a second local elevation on a front side of the respective second subregions, the front side is not etched, in particular at positions of the further connecting bars. When singulating the components, the further connecting bars can be severed.

In top view, the second local elevation is located in particular between an edge region of the second subregion adjacent to the second local elevation and a depression or a mounting surface of the second subregion. The second subregions of adjacent lead frames may be mechanically connected to each other via connecting bars. The double-etching to form the second local elevation is performed on a front side of the respective second subregions, wherein the front side is not etched, for example, at the positions of the connecting bars. The connecting bars may be deepened during the etching process. Due to the double-etching, surfaces or side surfaces of the local elevation and/or of the local depression of the first and/or the second subregion may have etch traces. The mounting surface of the first and/or the second subregion may also have etch traces.

After singulating, the components each have a semiconductor chip and a housing, wherein the housing comprises the lead frame and the housing body. The housing body can be anchored to the local elevations or depressions of the lead frame. In particular, due to the local elevations, harmful gas diffusion through the package to the semiconductor chip can be significantly reduced or prevented.

For increasing corrosion stability, the housing can be additionally sealed from the side. The lateral sealing can also be improved by forming depressions, in particular undercut depressions. In addition, the material of the housing body can be deposited directly onto the lead frame, which is formed of copper, for example, by the casting process or the plastic molding process, with any necessary NiPdAg plating taking place only subsequently, since a casting/molding material adheres significantly better to a copper layer than to a silver layer. It is also possible that surfaces of the lead frame are roughened to increase adhesion of the potting material to the lead frame. In addition, targeted casting/molding materials with low diffusion rates can be used. It is conceivable that the housing or housing body is additionally coated to further reduce harmful gas diffusion.

The method described here is particularly suitable for the production of a component described here. The features described in connection with the component can therefore also be used for the method, and vice versa.

### BRIEF DESCRIPTION OF THE DRAWINGS

Further embodiments and further developments of the component or of the method for producing the component will be apparent from the exemplary embodiments explained below in connection with FIGS. 1A to 5C.

FIGS. 1A, 1B, 1C, and 1D show schematic illustrations of an embodiment of a component in top view and in various sectional views;

FIGS. 2A and 2B show schematic illustrations of further embodiments of a component, each in top view;

FIGS. 3A, 3B and 3C show schematic illustrations of a further embodiment of a component in top view and in various sectional views;

FIGS. 4A, 4B and 4C show schematic illustrations of a further embodiment of a component in top view and in various sectional views; and

FIGS. 5A, 5B and 5C show schematic illustrations of further embodiments of a component, each in top view.

### DETAILED DESCRIPTION OF ILLUSTRATIVE EMBODIMENTS

Identical, equivalent or equivalently acting elements are indicated with the same reference numerals in the figures. The figures are schematic illustrations and thus not necessarily true to scale. Comparatively small elements and particularly layer thicknesses can rather be illustrated exaggeratedly large for the purpose of better clarification.

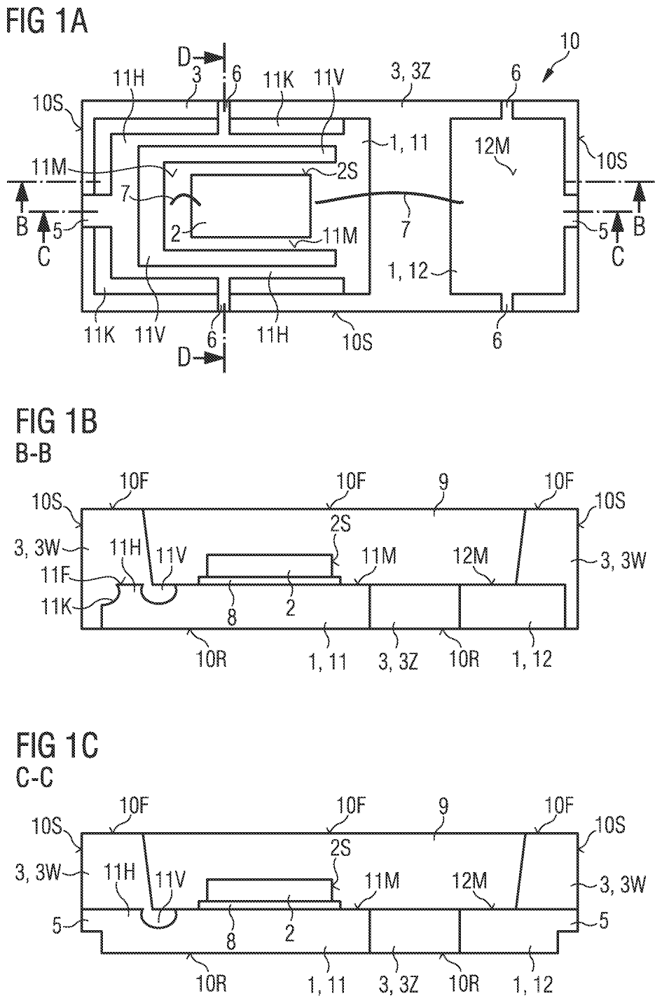

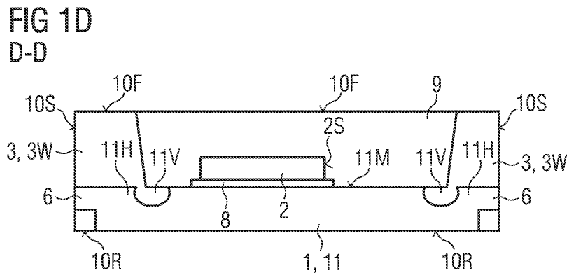

FIG. 1A shows a schematic top view of a component 10. FIGS. 1B, 1C and 1D show such a component 10 along the singulating line BB, CC or DD shown in FIG. 1A.

The component 10 has a lead frame 1, a semiconductor chip 2 arranged on the lead frame 1 and a housing body 3. In lateral directions, both the lead frame 1 and the semiconductor chip 2 are enclosed, in particular fully enclosed, by the housing body 3.

The lead frame 1 has a first subregion 11 and a second subregion 12 spatially spaced from the first subregion 11 by an intermediate region 3Z. As shown schematically in FIGS. 1A and 1B, both the first subregion 11 and the second subregion 12 are laterally surrounded, in particular completely surrounded, by the housing body 3. In particular, the housing body 3 is formed in one piece. Via the housing body 3, the subregions 11 and 12 of the lead frame 1 are mechanically connected to each other. The intermediate region 3Z may be completely filled by material of the housing body 3.

In a top view of a front side 10V of the component 10, the first subregion 11 or the second subregion 12 is only partially covered by the housing body 3. The first subregion 11 and the second subregion 12 have at least one solder control structure 5 and connecting bars 6. The solder control structure 5 may be step-shaped. The connecting bars 6 may have a smaller vertical thickness than the solder control structure 5 or remaining areas of the first subregion 11 and/or of the second subregion 12. The connecting bars 6 and/or the solder control structures 5 may be formed locally on outer side surfaces of the first subregion 11 or of the second subregion 12, for example in the form of a lateral protrusion in each case.

In particular, all lateral side surfaces of the subregions 11 and 12 are covered, in particular completely covered, by the housing body 3 except for the connecting bars 6 and/or the solder control structures 5. The solder control structures 5 can thus be seen from the outside. If the component 10 is soldered on an external carrier, for example on a printed circuit board, the amount of solder material can be controlled with the aid of the solder control structures 5. As lateral protrusions, the connecting bars 6 and the solder control structures 5 can serve as additional anchoring structures for fastening the housing body 3 to the lead frame 1.

In a top view of a rear side 10R of the component 10, the subregions 11 and 12 are freely accessible in regions. The rear side 10R of the component 10 can be formed in regions by surfaces of the housing body 10 and in regions by surfaces of the subregions 11 and 12 of the lead frame 1.

The first subregion 11 of the lead frame 1 has a depression 11V, in particular an inner depression 11V. According to FIGS. 1B, 1C and 1D, the depression 11V has curved, rounded, in particular concavely curved side walls.

The first subregion 11 has a sunken edge region 11K. In particular, the edge region 11K is an outer depression of the first subregion 11. According to FIG. 1B, the edge region 11K has curved, rounded, in particular concavely curved surface. Apart from this, it is possible that the surface of the edge region 11K is convex. However, a concave edge region 11K increases the mechanical stability with respect to the adhesion of the housing body 3 to the lead frame 1. Delamination or gap formation between the housing body 3 and the lead frame 1 is made more difficult or prevented by the concave edge region 11K.

The first subregion 11 has a first local elevation 11H. As shown in FIGS. 1A and 1B, the local elevation 11H is located along the lateral direction between the depression 11V and the edge region 11K. In particular, side surfaces of the local elevation 11H are formed by surfaces of the depression 11V and the edge region 11K. Thus, the local elevation 11H may be directly adjacent to the depression 11V and the edge region 11K.

In particular, the first subregion 11 having the depression 11V and the edge region 11K is a partially etched subregion 11 of the lead frame 1. Double-etching may be performed to form the local elevation 11H. Except for a front-side surface 11F of the local elevation 11H, surfaces of the local elevation 11H may have etch traces. In a double-etching process, two spatially spaced regions of the first subregion 11 are etched, and after the double-etching, local depressions 11V and 11K are formed in the two regions that continue to be spatially spaced. Between the two local depressions 11V and 11K there is an intermediate region which is not or hardly etched and thus after the double-etching forms the local elevation 11H between the two local depressions 11V and 11K.

The first subregion 11 has an overall vertical height H1. A ratio of a vertical depth T1 of the depression 11V to the total vertical height H1, i.e. T1/H1, may be from ¼ and to ¾, for example from ¼ to ½ or from ½ to ¾. The ratio T1/H1 can be 0.5±0.1. For example, the vertical depth T1 is from 50 μm to 150 μm, for instance between from 50 μm to 100 μm or from 100 μm to 150 μm, preferably around 100 μm for a total height H1=200 m. A minimum lateral width of the depression 11V, the edge region 11K and/or the local elevation 11H may be 30 μm, 50 μm, 70 μm, 100 μm, 150 μm or 200 μm. For example, a width of the depression 11V, the edge region 11K, and/or the local elevation 11H may be from 30 μm to 300 μm, for instance from 50 μm to 250 μm, or from 50 μm to 150 μm. However, the first subregion 11 is not limited to the dimensions mentioned above.

The first subregion 11 has a mounting surface 11M on which the semiconductor chip 2 is arranged. In at least one lateral direction or in several lateral directions, the mounting surface 11M is bounded by the local depression 11V. In particular, the mounting surface 11M is directly adjacent to the local depression 11V. The mounting surface 11M shown in FIGS. 1A, 1B, 1C, and 1D may be a non-etched surface of the first subregion 11 that is partially enclosed by the U-shaped depression 11V in three lateral directions. In particular, the mounting surface 11M and the front-side surface 11F of the local elevation 11H are at the same vertical height within the manufacturing tolerances. Referring to FIG. 1A, the mounting surface 11M and the front-side surface 11F of the local elevation 11H may form a continuous plane at the same vertical height.

In a top view of the mounting surface 11M, the first local elevation 11H or the local depression 11V extends along at least two or three side surfaces 2S of the semiconductor chip 2. The first local elevation 11H and the local depression 11V extend parallel to each other, in particular parallel to the depressed edge region 11K. As schematically shown in FIG. 1A, the first subregion 11 has an edge region facing the second subregion 12, which is not lowered, for example is not etched. This edge region has a surface that may be on the same vertical plane as the mounting surface 11M or a front-side surface 11F of the local elevation 11H.

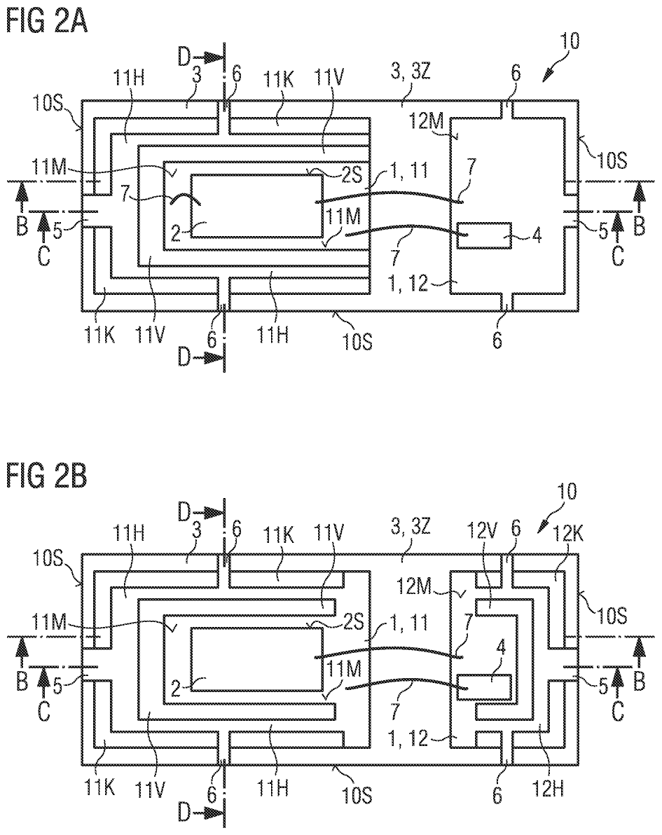

The semiconductor chip 2 is attached to the mounting surface 11M by a connecting layer 8. The connecting layer 8 may be electrically conductive or electrically insulating. According to FIG. 1A, the semiconductor chip 2 is electrically conductively connected to the first subregion 11 of the lead frame 1 via an electrical connection 7, which may be a wiring structure or a bonding wire. Deviating from this, it is possible that the semiconductor chip 2 is electrically conductively connected to the first subregion 11 via its rear side via the connecting layer 8, which is in particular formed from an electrically conductive material (see FIG. 2B).

The semiconductor chip 2 is electrically conductively connected to the second subregion 12 of the lead frame 1 via a further electrical connection 7, which bridges the intermediate region 3Z in top view. The first subregion 11 and the second subregion 12 are assigned to different electrical polarities of the component 10. It is possible that the component 10 can be electrically contacted externally exclusively at its rear side via the subregions 11 and 12.

As schematically shown in FIGS. 1B, 1C and 1D, the housing body 3 has an opening surrounded by housing walls 3 W in lateral directions. The semiconductor chip 2 is thus arranged on the mounting surface 11M within the opening, and the opening may be partially or completely filled by an encapsulation layer 9. The encapsulation layer 9 may be formed to be radiation-transmissive. It is possible that the encapsulation layer 9 comprises a radiation-transmissive matrix material, for instance an epoxy material or silicone, wherein scattering particles, reflection particles and/or phosphors are embedded. A front side 10F of the component 10 may be formed by surfaces of the encapsulation layer 9 and the housing body 3. Side surfaces 10S of the component 10 may be formed by surfaces of the housing body 3, the interconnection ridges 6, and/or the solder control structures 5.

The exemplary embodiment of a component 10 shown in FIG. 2A is substantially the same as the component 10 shown in FIG. 1A. In contrast, the local depression 11V, the local elevation 11H, or the depressed edge region 11K extends along the lateral direction to an outer edge of the first subregion 11, wherein the outer edge is adjacent to the intermediate portion 3Z and thus faces the second subregion 12 of the lead frame 1. In top view of the front side 10F of the component 10, the mounting surface 11M is completely separated from the local elevation 11H by the local depression 11V. The depressed edge region 11K extends along the entire three edges of the first subregion 11.

As a further difference to FIG. 1A, the component 10 shown in FIG. 2A has a protection diode 4 on a mounting surface 12M of the second subregion 12 of the lead frame 11. The protection diode 4 may be connected in parallel or anti-parallel with the semiconductor chip 2 via another electrical connection 7. For example, the protection diode 4 is an ESD protection diode.

The exemplary embodiment of a component 10 shown in FIG. 2B is substantially the same as the component 10 shown in FIG. 1A but with the protection diode 4 shown in FIG. 2A. While a front side of the second subregion 12 illustrated in FIGS. 1A and 2A is unstructured, the second subregion 12 illustrated in FIG. 2B may have a local depression 12V, a local elevation 12H, and a depressed edge region 12K very similar to the first subregion 11. The local depression 12V and the local elevation 12H on the front side of the second subregion 12 may be referred to as the second local depression 12V and the second local elevation 12H, respectively.

The second local depression 12V, the second local elevation 12H and the depressed edge region 12K of the second subregion 12 may have similar geometry and similar functions as the first local depression 11V, the first local elevation 11H, and the depressed edge region 11K of the first subregion 11, respectively. In the present disclosure, therefore, features described in connection with the first local depression 11V, the first local elevation 11H and the sunken edge region 11K of the first subregion 11 may also be used for the second local depression 12V, the second local elevation 12H and the sunken edge region 12K of the second subregion 12, respectively, or may at least be used analogously, and vice versa.

Analogous to the first subregion 11, the second subregion 12 may have an overall vertical height H2. A ratio of a vertical depth T2 of the depression 12V to the total vertical height H2, i.e. T2/H2, may be from ¼ to ¾, for example from ¼ to ½ or from ½ to ¾. The ratio T2/H2 can be 0.5±0.1. For example, the vertical depth T2 is from 50 μm to 150 μm, for instance from 50 μm to 100 μm or from 100 μm to 150 μm, preferably around 100 μm for a total height H2=200 μm. A minimum lateral width of the depression 12V, the edge region 12K, and/or the local elevation 12H may be 30 μm, 50 μm, 70 μm, 100 μm, 150 μm, or 200 μm. For example, a width of the depression 12V, the edge region 12K, and/or the local elevation 12H may be from 30 μm to 300 μm, for instance from 50 μm to 250 μm, or from 50 μm to 150 μm. However, the first subregion 12 is not limited to the dimensions mentioned above.

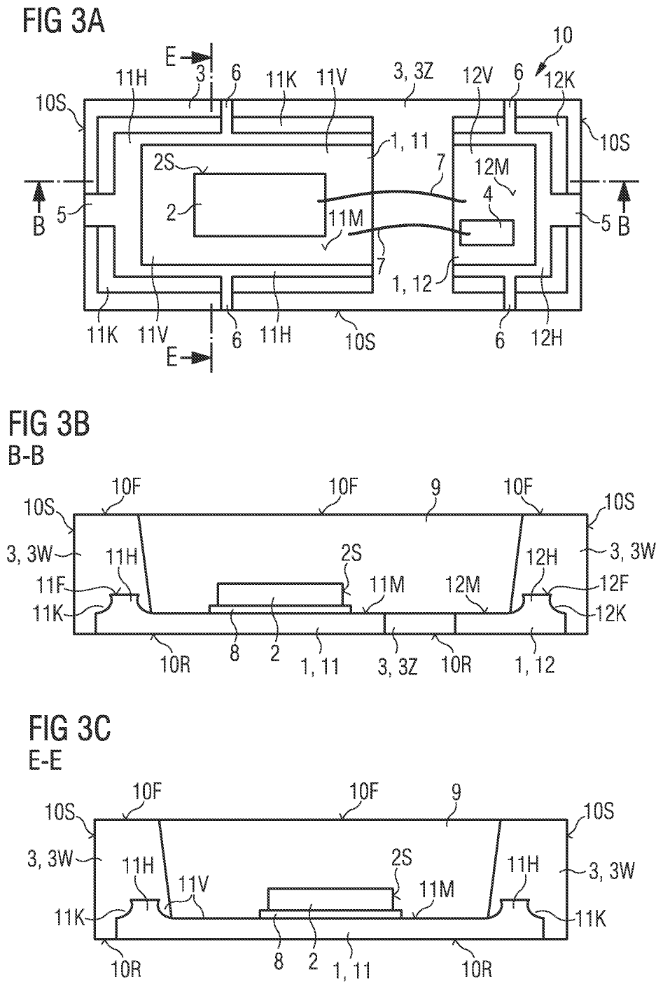

The exemplary embodiment of a component 10 shown in FIG. 3A is substantially the same as the exemplary embodiment of a component 10 shown in FIG. 2B, except that the depressed edge regions 11K and 12K shown in FIG. 3A are formed along the entire three edges of the respective subregions 11 and 12 in a manner very analogous to FIG. 2A. Further, the local depressions 11V and 12V and the local raised regions 11H and 12H extend along the lateral direction to an outer edge of the first subregion 11 or to an outer edge of the second subregion 12, wherein the outer edge of the first subregion 11 or the second subregion 12 is directly adjacent to the intermediate region 3Z.

As a further difference from the embodiments shown in FIGS. 1A to 2B, the mounting surface 11M of the first subregion 11 and the mounting surface 12M of the second subregion 12 are each formed by a bottom surface of the local depression 11V or 12V. Thus, the semiconductor chip 2 is disposed in the depression 11V. The protection diode 4 is arranged in the depression 12V. Due to the depressions 11V and 12V, a vertical thickness of the lead frame 1 at the positions of the mounting surfaces 11M and 12M can be reduced, as a result of which the component 10 can be made overall flatter and an improvement in terms of thermal conductivity or heat dissipation is obtained by thinning the lead frame 1. A lead frame 1 as shown in FIG. 3A may be referred to as a semi-etched lead frame 1.

FIGS. 3B and 3C show the component 10 shown in FIG. 3A along the singulating lines BB and EE. Referring to FIG. 3B or 3C, the first local elevation 11H protrudes along the vertical direction beyond the mounting surface 11M of the first subregion 11. In particular, the mounting surface 11M is bounded by the first local elevation 11H in at least one lateral direction, for instance in three lateral directions. In this regard, it is possible that the first subregion comprises a front-side partial surface which, in top view, is arranged between the first local elevation and the mounting surface. In top view, the front-side partial surface may be covered in regions or completely by a material of the housing body 3.

Referring to FIG. 3B, the second local elevation 12H projects along the vertical direction beyond the mounting surface 12M of the second subregion 12. The second local elevation 12H has a front-side surface 12F that is at a higher vertical level than the mounting surface 12M. It is possible that the front-side surface 12F of the second subregion 12 and the front-side surface 11F of the first subregion 11 are on the same vertical plane. In a top view of the front side 10F of the component 10, the housing body 3 completely covers the second local elevation 12H. The mounting surface 12M is bounded by the second local elevation 12H in at least one lateral direction, for instance in three lateral directions.

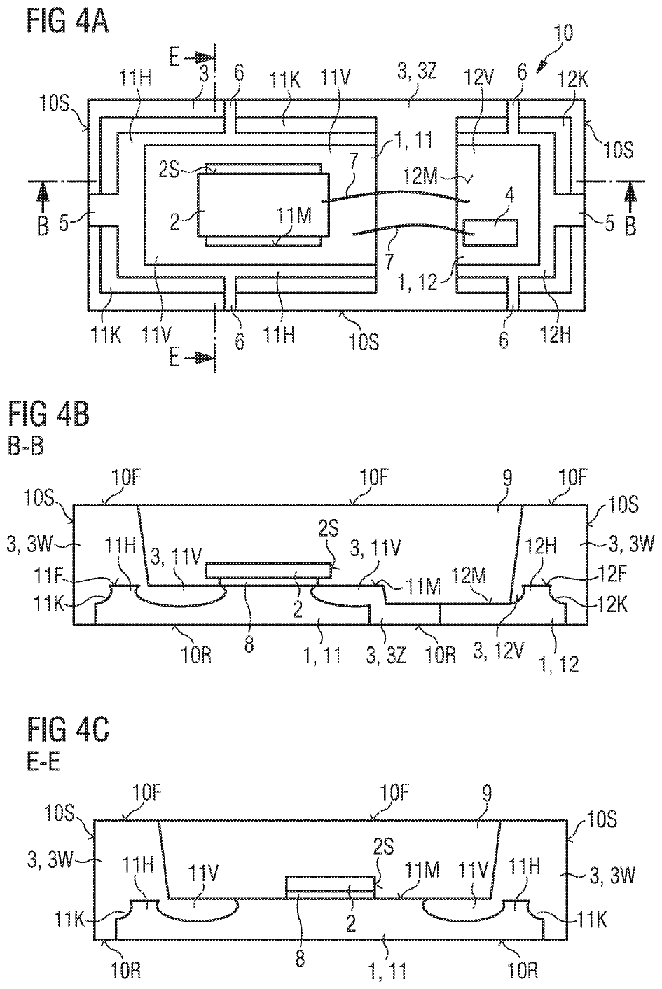

The embodiment of a component 10 shown in FIGS. 4A, 4B and 4C is substantially the same as the embodiment of a component 10 shown in FIGS. 3A, 3B, and 3C, respectively, but with the difference that the mounting surface 11M is formed in an island-like manner within the depression 11V.

In this case, the depression 11V may be completely filled with a material of the housing body 3. Compared to the preceding exemplary embodiments, the depression 11V has an enlarged extent. Furthermore, the semiconductor chip 2 is located in close proximity to the local depression 11V. In this case, the local depression 11V additionally serves as a cavity providing space, for example, for phosphors, scattering particles or reflection particles for instance titanium oxide and below the mounting surface 11M. Overall, the total height of the component 10 can thus be further reduced. In particular, the mounting surface 11M is located on the same vertical plane as a front-side surface 11F of the first local elevation 11H. In particular, since the mounting surface 11M is a non-etched region of the first subregion 11, the mounting surface 11M may be particularly planar.

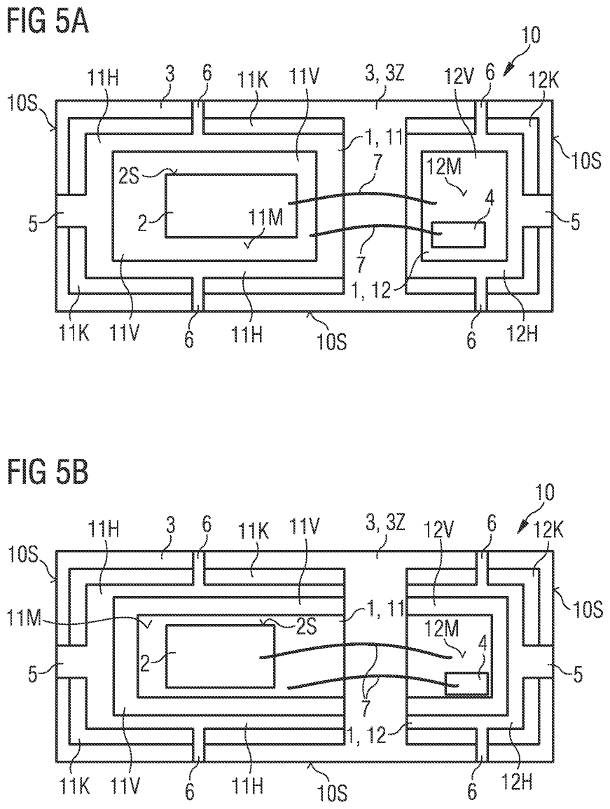

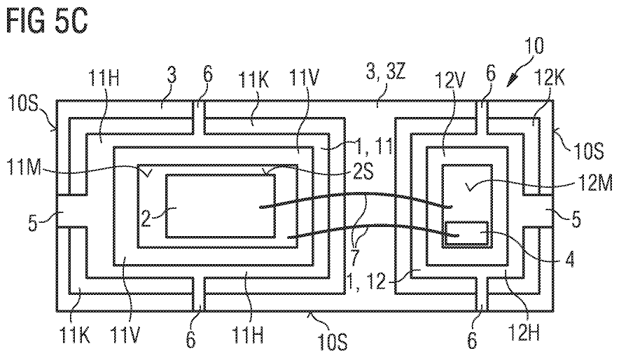

The exemplary embodiment of a component 10 shown in FIG. 5A is substantially the same as the component 10 shown in FIG. 3A, except that the first local elevation 11H completely surrounds the first local depression 11V or the mounting surface 11M of the first subregion 11 in lateral directions. Very analogously to the first subregion 11, the second local elevation 12H may completely surround the second local depression 12V or the mounting surface 12M of the second subregion 12 in lateral directions.

The embodiment of a component 10 shown in FIG. 5B is substantially the same as the component 10 shown in FIG. 2B, except that the local depression 11V and 12V, the local elevations 11H and 12H, and the depressed edge regions 11K and 12K extend along the lateral direction to an outer edge of the first subregion 11 or to an outer edge of the second subregion 12, wherein the outer edge of the first subregion 11 or the second subregion 12 are directly adjacent to the intermediate region 3Z.

The exemplary embodiment of a component 10 shown in FIG. 5C corresponds essentially to the component 10 shown in FIG. 2B, but with the difference that the local depression 11V and 12V, the local elevations 11H and 12H, and the lowered edge regions 11K and 12K are each formed in a frame-like manner and thus fully enclose the semiconductor chip 2 or the protection diode 4 in each case in top view. The mounting surface 11M or 12M may be formed in an island-like manner. This is shown schematically in FIGS. 4A, 4B and 4C, for example. In this case, it is conceivable that the local depression 11V and/or the local depression 12V may not be completely filled by a material of the housing body 3. The island-like formed mounting surface 11M or 12M can be free from being covered by the material of the housing body 3.

The invention is not restricted to the exemplary embodiments by the description of the invention made with reference to the exemplary embodiments. The invention rather comprises any novel feature and any combination of features, including in particular any combination of features in the claims, even if this feature or this combination is not itself explicitly indicated in the claims or exemplary embodiments.

1-20. (canceled)

21. A component comprising:
a lead frame;
a semiconductor chip; and
a housing body,
wherein the lead frame has a first subregion and a second subregion laterally spaced from the first subregion,
wherein the housing body laterally encloses the first subregion and the second subregion and thereby mechanically connects the first subregion to the second subregion,
wherein the semiconductor chip is arranged on a mounting surface of the first subregion and is electrically conductively connected to the subregions of the lead frame,
wherein the first subregion has a first local elevation, which vertically projects beyond at least one edge region of the first subregion, and, in top view of the mounting surface, at least partially surrounds the semiconductor chip, and
wherein, in the top view of the mounting surface, the housing body completely covers the first local elevation and does not cover the semiconductor chip.

22. The component according to claim 21, wherein, in the top view of the mounting surface, the first local elevation extends along at least two or three side surfaces of the semiconductor chip.

23. The component according to claim 21, wherein, in the top view of the mounting surface, the first local elevation completely encloses the semiconductor chip.

24. The component according to claim 21, wherein the first local elevation has a front-side surface located at the same vertical height as the mounting surface of the first subregion.

25. The component according to claim 21, wherein the first subregion has a first local depression adjoining the first local elevation, the first local depression being filled by a material of the housing body.

26. The component according to claim 25, wherein the first local depression and the first local elevation are parallel to each other along lateral directions.

27. The component according to claim 25, wherein, in the top view of the mounting surface, the first local depression extends along at least two or three side surfaces of the semiconductor chip.

28. The component according to claim 25, wherein the first local depression laterally bounds the mounting surface and is completely filled by the material of the housing body, the mounting surface being free from being covered by the material of the housing body.

29. The component according to claim 21,
wherein the first local elevation projects along a vertical direction beyond the mounting surface of the first subregion,
wherein the mounting surface directly adjoins first local depression, and
wherein the first subregion has a front-side partial surface which, in the top view, is arranged between the first local elevation and the mounting surface,
wherein the front-side partial surface, in the top view, is covered in regions by a material of the housing body.

30. The component according to claim 21, wherein the first local elevation is U-shaped or frame-shaped and partially or completely encloses the mounting surface.

31. The component according to claim 21, wherein at least one edge region or a plurality of edge regions of the first subregion is formed in a curved manner at least in regions.

32. The component according to claim 21, wherein the first subregion is one piece with the first local elevation.

33. The component according to claim 21, wherein the second subregion has a second local elevation vertically projecting beyond one edge region of the second subregion, and wherein the first local elevation and the second local elevation have the same geometry in the top view.

34. The component according to claim 21, further comprising a protection diode arranged on the second subregion of the lead frame and connected antiparallel with the semiconductor chip.

35. The component according to claim 21, wherein the first subregion and/or the second subregion have/has a solder control structure being an integral part of the lead frame, and wherein the solder control structure is visible from an outside on a side surface of the component.

36. A method for producing the component according to claim 21, the method comprising:
performing a double-etching of a front side of the first subregion of the lead frame for forming the first local elevation on the front side; and
forming the housing body,
wherein the housing body completely covers the first local elevation and is anchored to the first local elevation.

37. A method for producing a plurality of components according to claim 21, the method comprising:
providing a plurality of lead frames, each comprising a first subregion and a second subregion, wherein the first subregions of neighboring lead frames are mechanically connected to one another via connecting bars;
performing double-etching for forming the first local elevation on a front side of the respective first subregions, wherein the front side is not etched at positions of the connecting bars; and
separating the components after forming the housing body, wherein the housing body and the connecting bars are severed.

38. The method according to claim 37,
wherein the second subregions of adjacent lead frames are mechanically connected to one another via further connecting bars, and
wherein, in performing the double-etching for forming a second local elevation on a front side of the respective second subregions, the front side is not etched at positions of the further connecting bars, and
wherein, when the components are separated, the further connecting bars are severed.

39. A component comprising:
a lead frame;
a semiconductor chip; and
a housing body,
wherein the lead frame has a first subregion and a second subregion laterally spaced from the first subregion,
wherein the housing body laterally encloses the first subregion and the second subregion and thereby mechanically connects the first subregion to the second subregion,
wherein the semiconductor chip is arranged on a mounting surface of the first subregion and is electrically conductively connected to the subregions of the lead frame,
wherein the first subregion has a first local elevation, which vertically projects beyond at least one edge region of the first subregion and, in top view of the mounting surface, at least partially surrounds the semiconductor chip,
wherein, in the top view of the mounting surface, the housing body completely covers the first local elevation and does not cover the semiconductor chip,
wherein the first subregion has a first local depression adjoining the first local elevation, the first local depression being completely filled by a material of the housing body,
wherein the mounting surface is formed as an island within the depression,
wherein the mounting surface directly adjoins the first local depression,
wherein the semiconductor chip is located in close proximity to the first local depression, and
wherein the first local depression additionally serves as a cavity providing space below the mounting surface for phosphors, scattering particles or reflection particles.

40. A component comprising:
a lead frame;
a semiconductor chip; and
a housing body,
wherein the lead frame has a first subregion and a second subregion laterally spaced from the first subregion,
wherein the housing body laterally encloses the first subregion and the second subregion and thereby mechanically connects the first subregion to the second subregion,
wherein the semiconductor chip is arranged on a mounting surface of the first subregion and is electrically conductively connected to the subregions of the lead frame,
wherein the first subregion has a first local elevation, which vertically projects beyond at least one edge region of the first subregion, and, in top view of the mounting surface, at least partially surrounds the semiconductor chip,
wherein, in the top view of the mounting surface, the housing body completely covers the first local elevation and does not cover the semiconductor chip, and
wherein the first local elevation projects along a vertical direction beyond the mounting surface of the first subregion.
